(19) United States
(12) Patent Application Publication
(10) Pub. No.: US 2025/0208774 A1
(43) Pub. Date: Jun. 26, 2025

(54) PROGRAMMABLE LOGIC BLOCK COMPRISING FLASH MEMORY ARRAY TO STORE CONFIGURATION DATA FOR PROGRAMMABLE LOGIC

(71) Applicant: Silicon Storage Technology, Inc., San Jose, CA (US)

(72) Inventors: Hieu Van Tran, San Jose, CA (US); Hien Pham, Ho Chi Minh (VN); Hung Bui, Bien Hoa (VN); Han Tran, Ho Chi Minh (VN); Nhan Do, Saratoga, CA (US); Parviz Ghazavi, San Jose, CA (US); Yuri Tkachev, Sunnyvale, CA (US); Gilles Festes, Fuveau (FR)

(21) Appl. No.: 18/435,943

(22) Filed: Feb. 7, 2024

Related U.S. Application Data
(60) Provisional application No. 63/613,008, filed on Dec. 20, 2023.

(51) Int. Cl. G06F 3/06

(52) U.S. Cl. CPC G06F 3/0632; G06F 3/0619; G06F 3/0679

(57) ABSTRACT

In one example, a system comprises a programmable logic block comprising programmable logic and a configuration block to store and provide configuration data to the programmable logic, the configuration block comprising a flash memory array to store the configuration data, and the flash memory array comprising an array of split-gate flash memory cells.

### PRIORITY CLAIM

This application claims priority to U.S. Provisional Patent Application No. 63/613,008, filed on Dec. 20, 2023, and titled, “Programmable Logic Block Comprising Flash Memory Array to Configure Programmable Logic,” which is incorporated by reference herein.

### FIELD OF THE INVENTION

Numerous examples are disclosed of a programmable logic block comprising a flash memory array to configure programmable logic.

### BACKGROUND OF THE INVENTION

The prior art includes non-volatile memories. For example, U.S. Pat. No. 5,029,130 (“the '130 patent”), which is incorporated herein by reference, discloses an array of split-gate non-volatile memory cells, which are a type of flash memory cells. Such a memory cell 110 is shown in FIG. 1. Each memory cell 110 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 110 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 110 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 110 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 110 for performing read, erase, and program operations:

TABLE NO 1
Operation of Flash Memory Cell 110 of FIG. 1

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split-gate memory cell configurations, which are other types of flash memory cells, are known. For example, FIG. 2 depicts a four-gate memory cell 210 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are 2 electrically connected or connectable to a voltage source. Programming is performed by energized electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 210 for performing read, erase, and program operations:

TABLE NO 2
Operation of Flash Memory Cell 210 of FIG. 2

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 V | | 0 | V | 0 V/−8 V | | 8-12 | V | 0 | V |
| Program | 1 | V | 0.1-1 | μA | 8-11 | V | 4.5-9 | V | 4.5-5 | V |

FIG. 3 depicts a three-gate memory cell 310, which is another type of split-gate flash memory cell. Memory cell 310 is identical to the memory cell 210 of FIG. 2 except that memory cell 310 does not have a separate control gate. The erase operation (whereby erasing occurs through use of the erase gate) and read operation are similar to that of the FIG. 2 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 310 for performing read, erase, and program operations:

TABLE NO 3
Operation of Flash Memory Cell 310 of FIG. 3

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | | |
|---|---|---|---|---|---|---|---|---|
| Program | 1 | V | 0.2-3 | μA | 4.5-8 | V | 6-9 | V |

FIG. 4 depicts stacked-gate memory cell 410, which is another type of flash memory cell. Memory cell 410 is similar to memory cell 210 of FIG. 1, except that floating gate 20 extends over the entire channel region 18, and control gate 22 (which here will be coupled to a word line) extends over floating gate 20, separated by an insulating layer. The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 410 and substrate 12 for performing read, erase, and program operations:

TABLE NO 4
Operation of Flash Memory Cell 410 of FIG. 4

| | CG | | BL | | SL | | Substrate | |
|---|---|---|---|---|---|---|---|---|
| Read | 2-5 | V | 0.6-2 | V | 0 | V | 0 | V |
| Erase | −8 to-10 V/0 V | | FLT | | FLT | | 8-10 V/15-20 V | |
| Program | 8-12 | V | 3-5 | V | 0 | V | 0 | V |

The prior art also includes programmable logic devices, which can form a digital logic design after being configured. Programmable logic devices can be reconfigured numerous times to form different digital logic designs. Examples of a programmable logic device include a programmable array logic (PAL), a programmable logic array (PLA), a complex programmable logic device (CPLD), and a field-programmable gate array (FPGA).

A programmable logic device is configured prior to operation, where configuration data is provided to the programmable logic device.

What is needed are improved methods and systems to utilize flash memory arrays comprising split-gate flash memory cells to store and deliver configuration data to a programmable logic device.

### SUMMARY OF THE INVENTION

In the systems and methods described herein, a system comprises one or more programmable logic blocks, optionally embedded on the same die. A programmable logic block comprises a configuration block and programmable logic. The configuration block comprises a flash memory device in which configuration data is stored and from which configuration data is delivered to the programmable logic during a configuration operation. The configuration block optionally comprises configuration data logic near the flash memory device, where there is little latency between the flash memory array and configuration data logic and where the configuration data logic delivers the configuration data from the flash memory device to the programmable logic. Storing configuration data in a flash memory device is a resilient way to store configuration data because, for example, the configuration data will be robust to errors caused by solar radiation and can be resistant to single event upset (SEU) or single event error (SEE) events.

### BRIEF DESCRIPTION OF THE DRAWINGS

FIG. 1 depicts a prior art split-gate flash memory cell.

FIG. 2 depicts another prior art split-gate flash memory cell.

FIG. 3 depicts another prior art split-gate flash memory cell.

FIG. 4 depicts a prior art stacked-gate gate flash memory cell.

FIG. 5 depicts a system comprising programmable logic blocks and circuitry.

FIG. 6A depicts an example of a programmable logic block.

FIG. 6B depicts another example of a programmable logic block.

FIG. 7A depicts an example of a programmable logic block.

FIG. 7B depicts another example of a programmable logic block.

FIG. 8A depicts an example of a programmable logic block.

FIG. 8B depicts another example of a programmable logic block.

FIG. 9 depicts another example of a programmable logic block.

FIG. 10 depicts another example of a programmable logic block.

FIG. 11A depicts the storing of a bit of configuration data with a first value in adjacent memory cells.

FIG. 11B depicts the storing of a bit of configuration data with a second value in adjacent memory cells.

FIG. 11C depicts the storing of a bit of configuration data with a first value in adjacent memory cells.

FIG. 11D depicts the storing of a bit of configuration data with a second value in adjacent memory cells.

FIG. 12A depicts the storing of bit of configuration data in adjacent memory cells of a first memory cell architecture.

FIG. 12B depicts the storing of bit of configuration data in adjacent memory cells of a second memory cell architecture/

FIG. 13 depicts a level shifter.

FIG. 14 depicts a current mirror.

FIG. 15 depicts a current mirror.

### DETAILED DESCRIPTION OF THE INVENTION

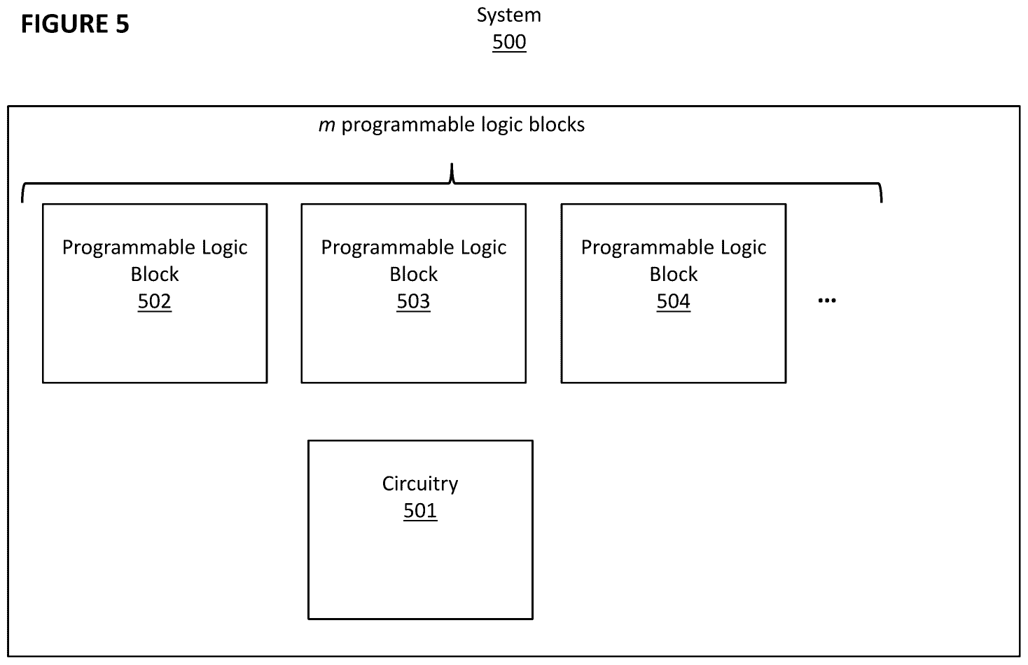

FIG. 5 depicts system 500, which comprises circuitry 501 and programmable logic blocks 502, 503, and 504. This example depicts three programmable logic blocks, but it is to be understood that system 500 comprises m programmable logic blocks, where m can range from 1 to any integer value. Programmable logic blocks 502, 503, 504 and any others can be identical to one or more of the others, or different. Circuitry 501 contains supporting circuitry for the operation of the m programmable logic blocks, such as routing circuitry, buffers, and other circuitry.

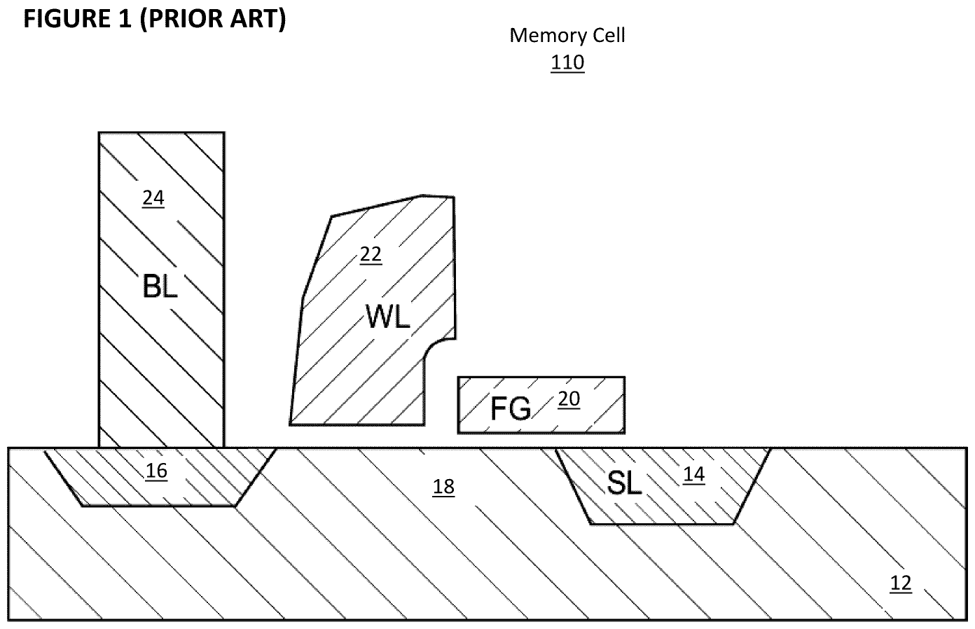

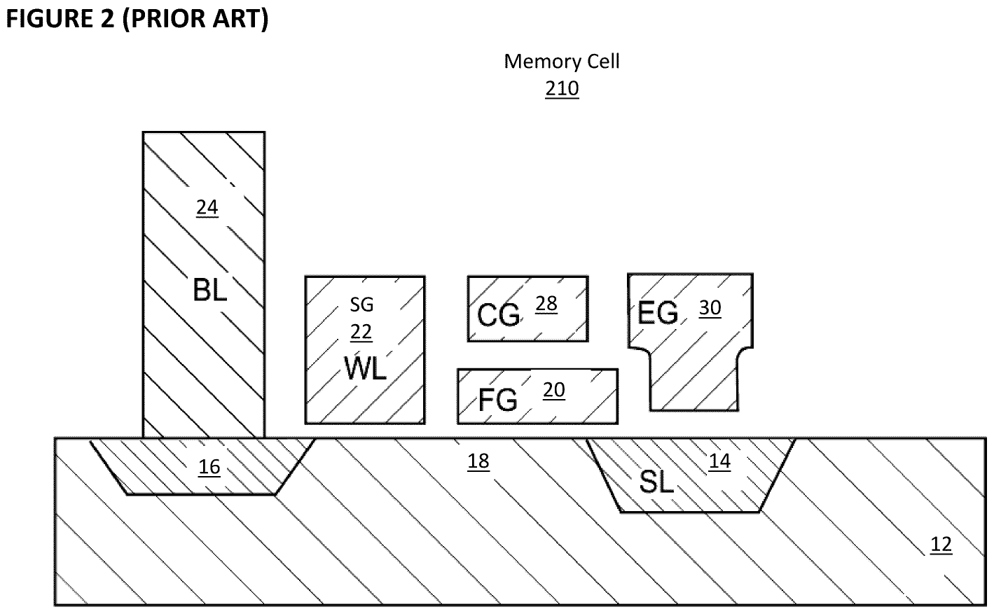

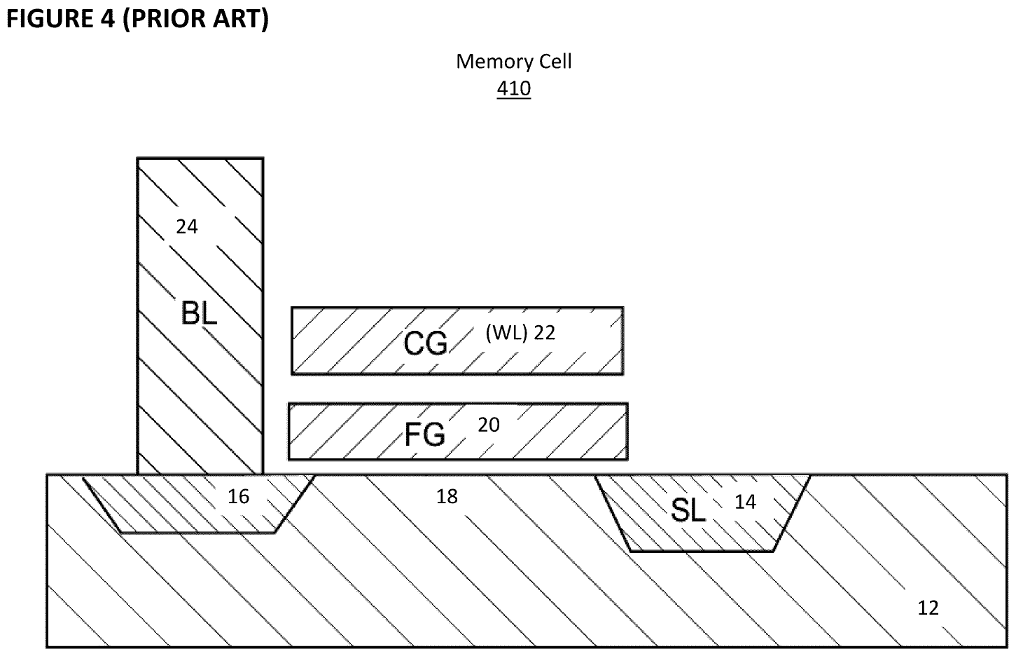

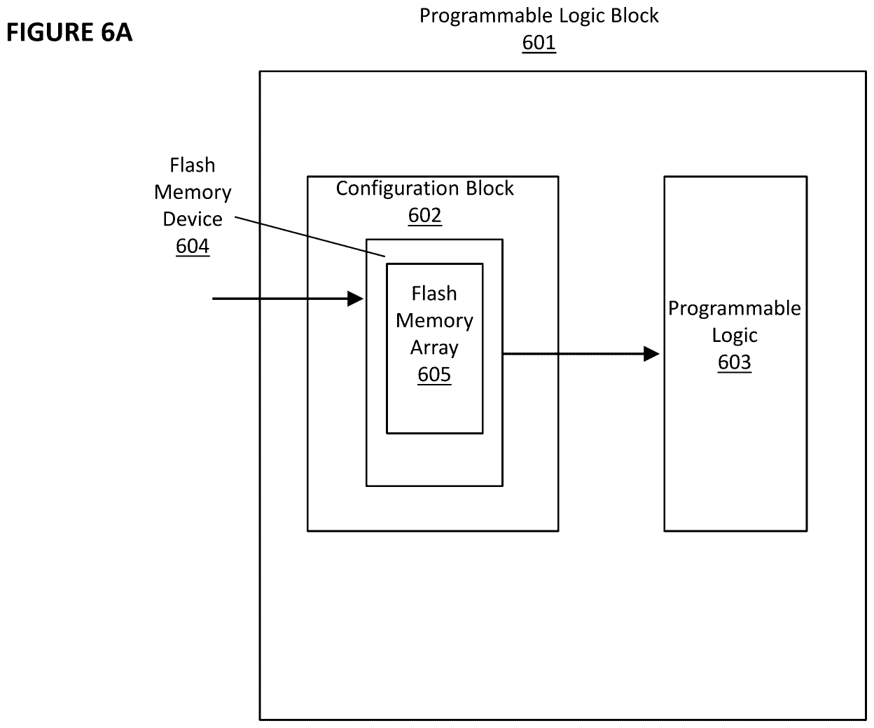

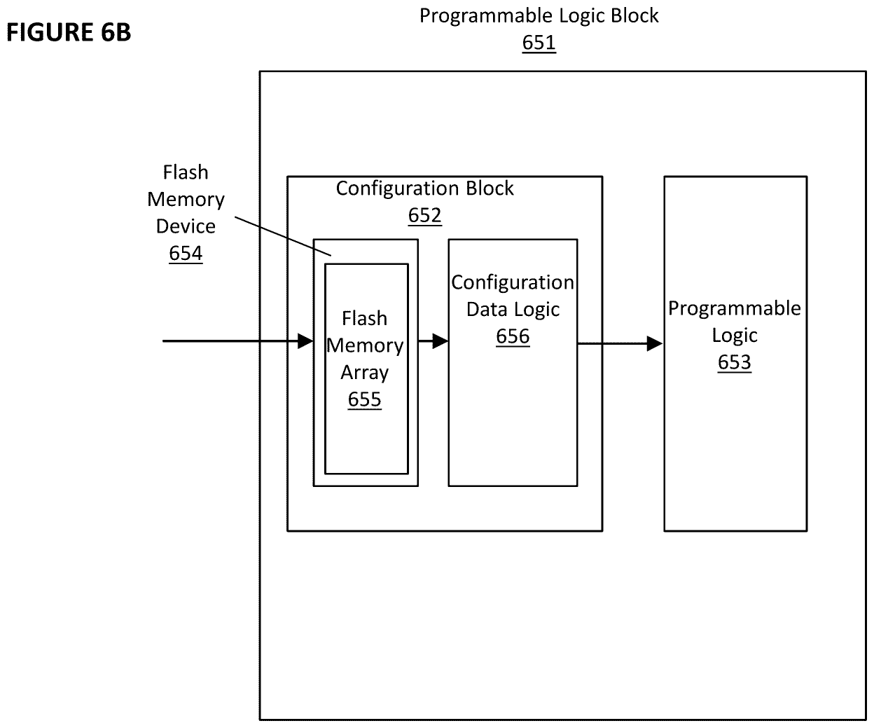

FIG. 6A depicts programmable logic block 601, which is an example that can be used for the m programmable logic blocks (such as programmable logic blocks 502, 503, and 504) in FIG. 5. Programmable logic block 601 comprises configuration block 602 and programmable logic 603. Configuration block 602 comprises flash memory device 604, which comprises flash memory array 605 and circuitry for operating flash memory array 605. Programmable logic 603 can comprise logic for performing particular functions. Flash memory array 605 is programmed to store configuration data that is used to configure programmable logic 603 to perform its particular function, or functions. Flash memory array 605 is an array of flash memory cells (such as cells following the architecture of memory cells 110, 210, 310, and 410 in FIGS. 1, 2, 3, and 4, respectively) arranged into rows and columns.

FIG. 6B depicts programmable logic block 651, which is an example that can be used for the m programmable logic blocks (such as programmable logic blocks 502, 503, and 504) in FIG. 5. Programmable logic block 651 is similar to programmable logic block 601 in FIG. 6A except that it also contains configuration data logic 656. Programmable logic block 651 comprises configuration block 652 and programmable logic 653. Configuration block 652 comprises flash memory device 654, which comprises flash memory array 605 and circuitry for operating flash memory array 655. Flash memory array 655 is an array of flash memory cells (such as cells following the architecture of memory cells 110, 210, 310, and 410 in FIGS. 1, 2, 3, and 4, respectively) arranged into rows and columns. Programmable logic 653 can comprise logic for performing particular functions. Flash memory array 655 is programmed to store configuration data that is used to configure programmable logic 653 to perform its particular function, or functions. Configuration data logic 656 receives signals from flash memory device 654 and does one or more of enhancing the signals such as by increasing or decreasing the voltage level of a ‘1’ bit and enhancing the signals by providing more functionalities for the outputs such as complementary signals or other functional logic signals and providing the enhanced configuration data to programmable logic 653 to configure programmable logic 653.

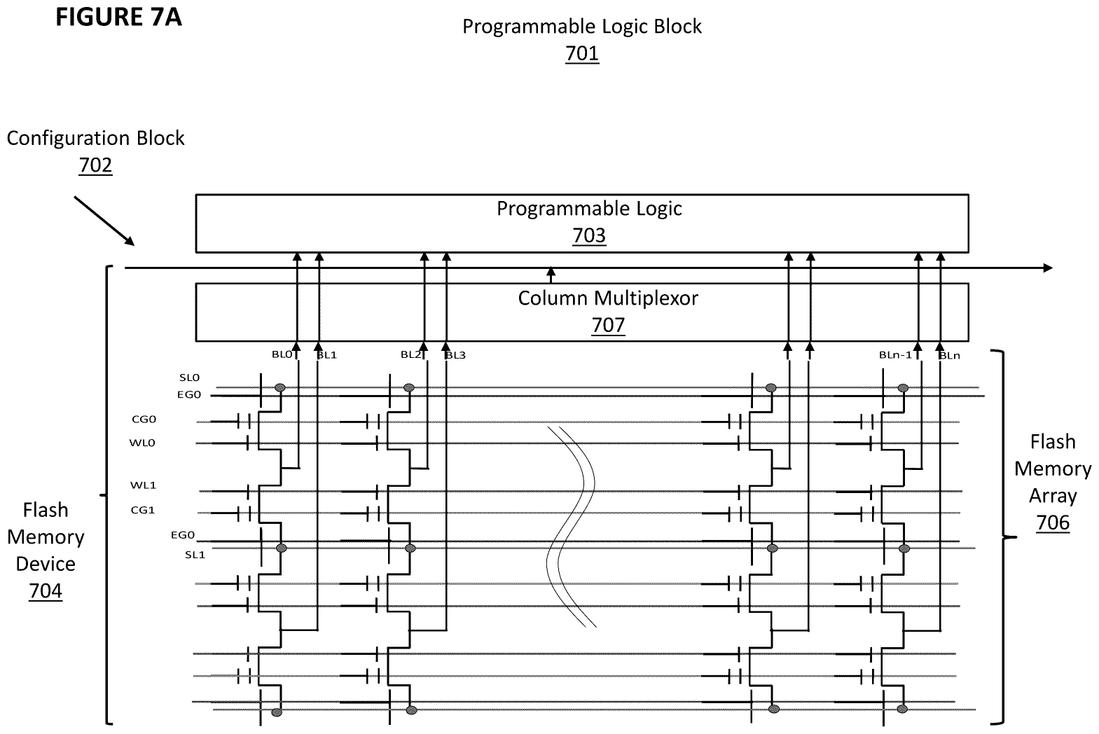

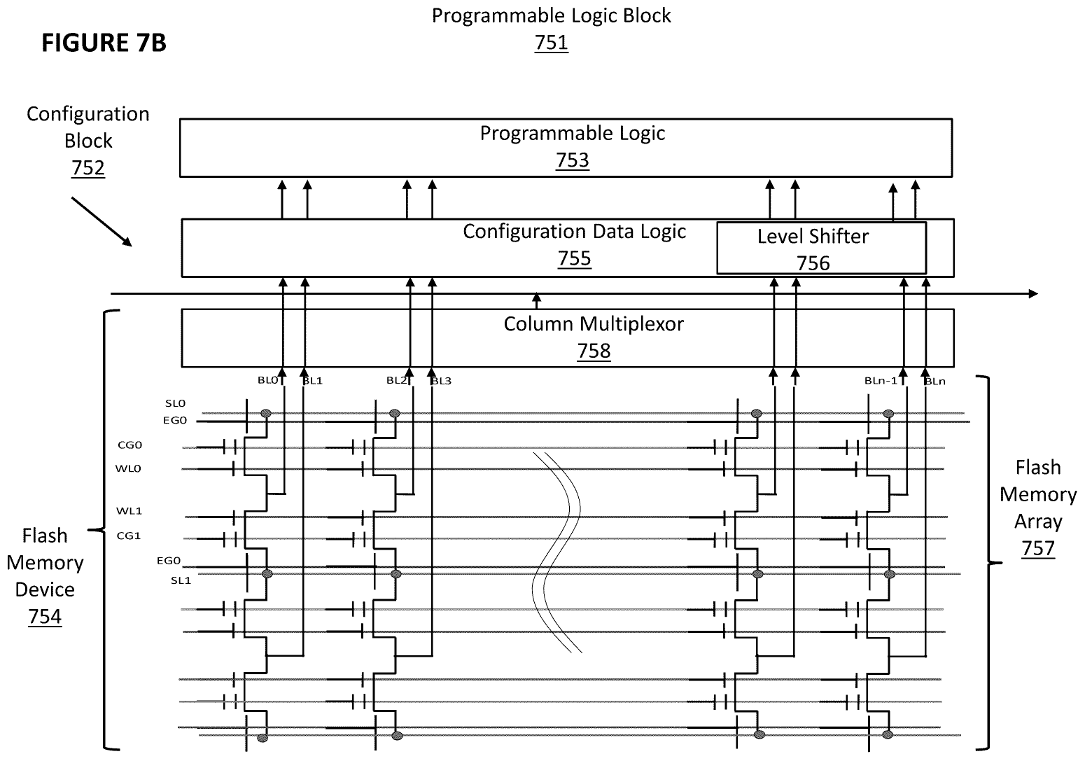

FIG. 7A depicts programmable logic block 701, which is an example of programmable logic block 601 in FIG. 6A. Programmable logic block 701 comprises configuration block 702 and programmable logic 703, which are examples of configuration block 602 and programmable logic 603 in FIG. 6A, respectively. Configuration block 702 comprises flash memory device 704 (which is an example of flash memory device 604 in FIG. 6A), which flash memory device 704 comprises flash memory array 706 and column multiplexor 707. Column multiplexor 707 is used to select bitlines of flash memory array 706 for programming or possibly sensing. Circuits for programming or for sensing are not shown. The sensing can be used to verify the cells are in programmed or erased states.

Flash memory array 706 comprises a plurality of flash memory cells arranged in rows and columns. Flash memory array 706 further comprises word lines coupled to word line terminals of flash memory cells, control gate lines coupled to control gate terminals of flash memory cells, source lines coupled to source line terminals of flash memory cells, erase gate lines coupled to erase gate terminals of flash memory cells, and bit lines coupled to bit line terminals of flash memory cells. In this example, the word lines, control gate lines, source lines, and erase gate lines are horizontal (i.e., arranged in a first direction) and the bit lines are vertical (i.e., arranged in a second direction perpendicular to the first direction).

Column multiplexor 707 is used during the programming operation of cells in flash memory array 706 by providing a programming current, IPROG, to the cell being programmed. Column multiplexor 707 also connects flash memory array 706 to sense amplifiers for use during read or verify operations. During a configuration operation of programmable logic 703, configuration data is read from flash memory array 706 and provided to programmable logic 703 by column multiplexor 707, which is controlled by a controller (not shown).

FIG. 7B depicts programmable logic block 751, which is an example of programmable logic block 651 in FIG. 6B. Programmable logic block 751 comprises configuration block 752 and programmable logic 753, which are examples of configuration block 652 and programmable logic 653 in FIG. 6B, respectively. Configuration block 752 comprises flash memory device 754 (which is an example of flash memory device 654 in FIG. 6B), which flash memory device 754 comprises flash memory array 757 and all-bitline column multiplexor 758, and configuration data logic 755 (which is an example of configuration data logic 655 in FIG. 6B).

Flash memory array 757 comprises a plurality of flash memory cells arranged in rows and columns. Flash memory array 757 further comprises word lines coupled to word line terminals of flash memory cells, control gate lines coupled to control gate terminals of flash memory cells, source lines coupled to source line terminals of flash memory cells, erase gate lines coupled to erase gate terminals of flash memory cells, and bit lines coupled to bit line terminals of flash memory cells. In this example, the word lines, control gate lines, source lines, and erase gate lines are horizontal (i.e., arranged in a first direction) and the bit lines are vertical (i.e., arranged in a second direction perpendicular to the first direction).

Column multiplexor 758 is used during the programming operation of cells in flash memory array 757 by providing a programming current, IPROG, to the cell being programmed. Column multiplexor 758 also connects flash memory array 757 to sense amplifiers for use during read or verify operations.

During a configuration operation of programmable logic 753, read signals (such as bit line current or voltages corresponding to the bit line current) corresponding to the stored configuration data are obtained from flash memory array 757. The read signals are provided to configuration data logic 755. Configuration data logic 755 does one or more of enhancing the read signals such as by increasing or decreasing the voltage level of a ‘1’ bit and enhancing the signals by providing more functionalities for the outputs such as complementary signals or other functional logic signals and providing the enhanced configuration data to programmable logic 753. In one example, configuration data logic 755 comprises level shifter 756, which receives voltages output from flash memory array 757, and generates output voltages of a different level than the received voltages for a “1” (e.g., from 0.7V to 1.8V) or optionally for a “0” (e.g., from 0.0V to 0.5V) depending on program or erase state of the memory cells.

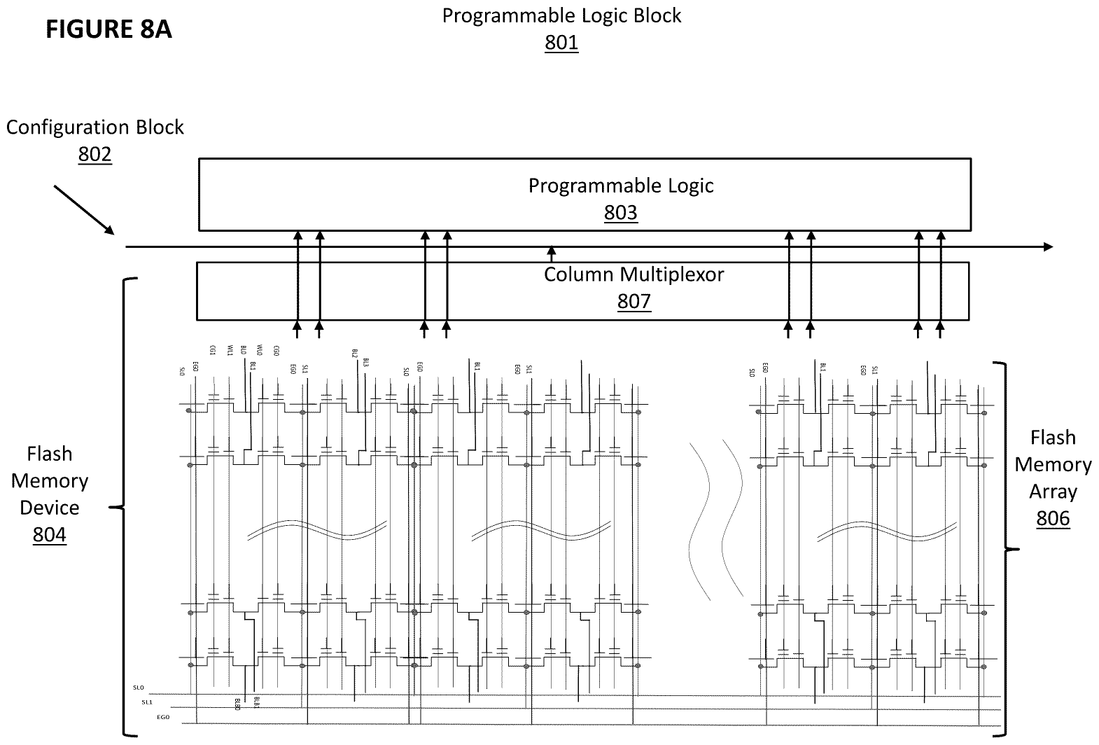

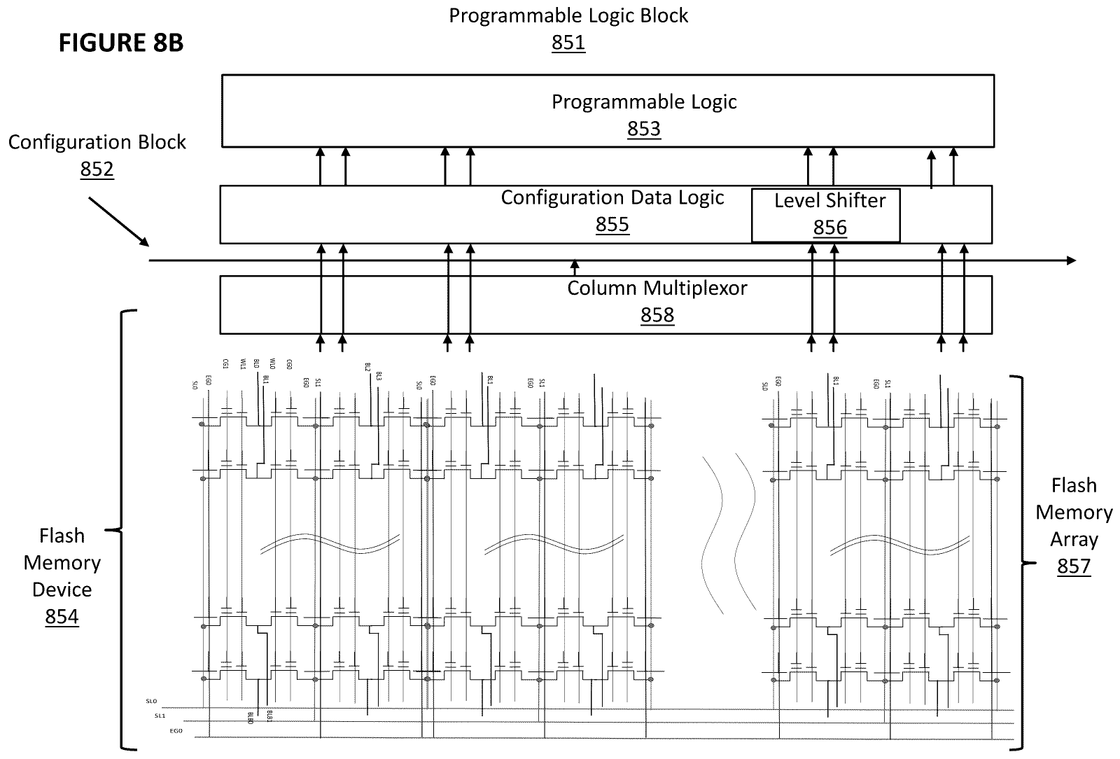

FIG. 8A depicts programmable logic block 801, which is an example of programmable logic block 601 in FIG. 6A. Programmable logic block 801 comprises configuration block 802 and programmable logic 803, which are examples of configuration block 602 and programmable logic 603 in FIG. 6A, respectively. Configuration block 802 comprises flash memory device 804 (which is an example of flash memory device 604 in FIG. 6A), which flash memory device 804 comprises flash memory array 806 and column multiplexor 807.

Flash memory array 806 comprises a plurality of flash memory cells arranged in rows and columns. Flash memory array 806 further comprises word lines coupled to word line terminals of flash memory cells, control gate lines coupled to control gate terminals of flash memory cells, source lines coupled to source line terminals of flash memory cells, erase gate lines coupled to erase gate terminals of flash memory cells, and bit lines coupled to bit line terminals of flash memory cells. In this example, the word lines, control gate lines, source lines, erase gate lines, and bit lines are arranged in a single direction (which on this page appear to be vertical).

Column multiplexor 807 is used during the programming operation of cells in flash memory array 806 by providing a programming current, IPROG, to the cell being programmed. Column multiplexor 807 also connects flash memory array 806 to sense amplifiers for use during read or verify operations. During a configuration operation of programmable logic 803, configuration data is read from flash memory array 806 and provided to programmable logic 803.

FIG. 8B depicts programmable logic block 851, which is an example of programmable logic block 651 in FIG. 6B. Programmable logic block 851 comprises configuration block 852 and programmable logic 853, which are examples of configuration block 652 and programmable logic 653 in FIG. 6B, respectively. Configuration block 852 comprises flash memory device 854 (which is an example of flash memory device 654 in FIG. 6B), which flash memory device 854 comprises flash memory array 857 and column multiplexor 858, and configuration data logic 855 (which is an example of configuration data logic 655 in FIG. 6B).

Flash memory array 857 comprises a plurality of flash memory cells arranged in rows and columns. Flash memory array 857 further comprises word lines coupled to word line terminals of flash memory cells, control gate lines coupled to control gate terminals of flash memory cells, source lines coupled to source line terminals of flash memory cells, erase gate lines coupled to erase gate terminals of flash memory cells, and bit lines coupled to bit line terminals of flash memory cells. In this example, the word lines, control gate lines, source lines, erase gate lines, and bit lines are arranged in a single direction (which on this page appear to be vertical).

Column multiplexor 858 is used during the programming operation of cells in flash memory array 857 by providing a programming current, IPROG, to the cell being programmed. Column multiplexor 858 also connects flash memory array 857 to sense amplifiers for use during read or verify operations.

During a configuration operation of programmable logic 853, read signals (such as bit line current or voltages corresponding to the bit line current) corresponding to the stored configuration data are obtained from flash memory array 857. The read signals are provided to configuration data logic 855 by column multiplexor 858. Configuration data logic 855 does one or more of enhancing the read signals such as by increasing or decreasing the voltage level of a ‘1’ bit and enhancing the signals by providing more functionalities for the outputs such as complementary signals or other functional logic signals and providing the enhanced configuration data to programmable logic 853. In one example, configuration data logic 855 comprises level shifter 856, which receives voltages output from a sense amplifier (not shown), which had generated those voltages in response to read signals (such as bit line current) from flash memory array 857.

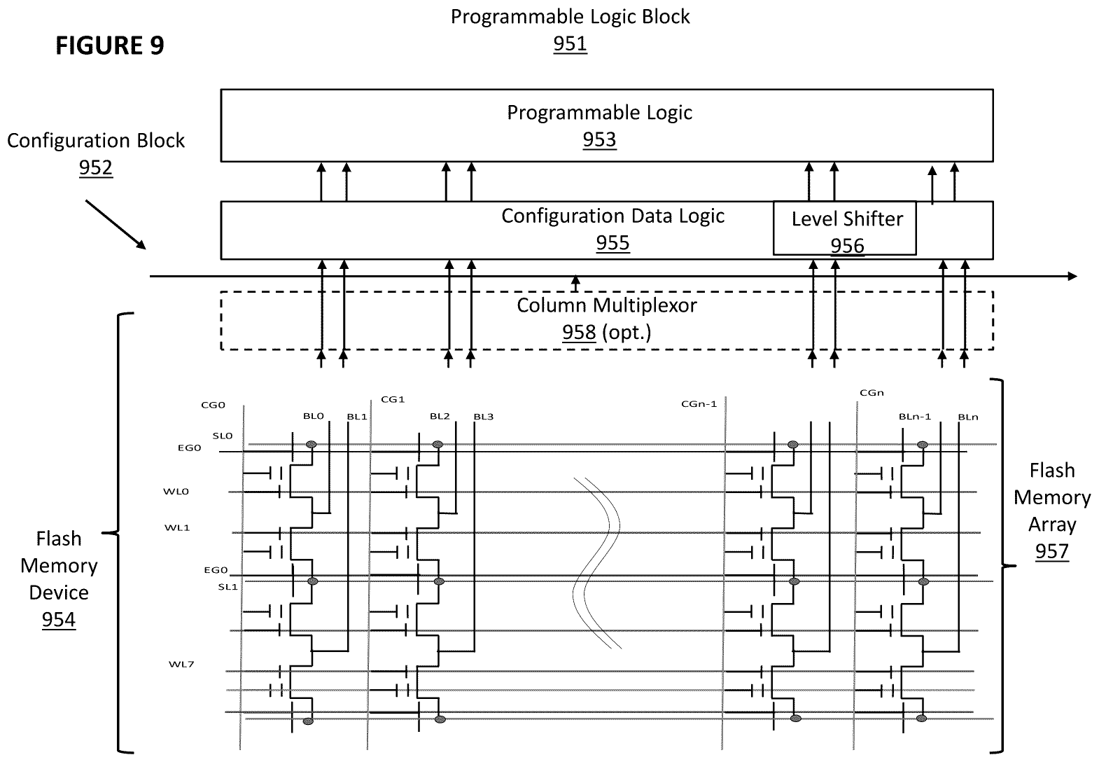

FIG. 9 depicts programmable logic block 951, which is an example of programmable logic block 651 in FIG. 6B. Programmable logic block 951 comprises configuration block 952 and programmable logic 953, which are examples of configuration block 652 and programmable logic 653 in FIG. 6B, respectively. Configuration block 952 comprises flash memory device 954 (which is an example of flash memory device 654 in FIG. 6B), which comprises flash memory device 954 comprises flash memory array 957 and, optionally, column multiplexor 958, and configuration data logic 955 (which is an example of configuration data logic 655 in FIG. 6B).

Flash memory array 957 comprises a plurality of flash memory cells arranged in rows and columns. Flash memory array 957 further comprises word lines coupled to word line terminals of flash memory cells, control gate lines coupled to control gate terminals of flash memory cells, source lines coupled to source line terminals of flash memory cells, erase gate lines coupled to erase gate terminals of flash memory cells, and bit lines coupled to bit line terminals of flash memory cells. In this example, the word lines, source lines, and erase gate lines are horizontal (i.e., arranged in a first direction) and the control gate lines and bit lines are vertical (i.e., arranged in a second direction perpendicular to the first direction).

Column multiplexor 958 is used during the programming operation of cells in flash memory array 957 by providing a programming current, IPROG, to the cell being programmed. Column multiplexor 958 also connects flash memory array 957 to sense amplifiers for use during read or verify operations.

During a configuration operation of programmable logic 953, read signals (such as bit line current or voltages corresponding to the bit line current) corresponding to the stored configuration data are obtained from flash memory array 957. The read signals are provided to configuration data logic 955 by column multiplexor 958. Configuration data logic 955 does one or more of enhancing the read signals such as by increasing or decreasing the voltage level of a ‘1’ bit and enhancing the signals by providing more functionalities for the outputs such as complementary signals or other functional logic signals and providing the enhanced configuration data to programmable logic 953. In one example, configuration data logic 955 comprises level shifter 956, which receives voltages output from a sense amplifier (not shown), which had generated those voltages in response to read signals (such as bit line current) from flash memory array 957.

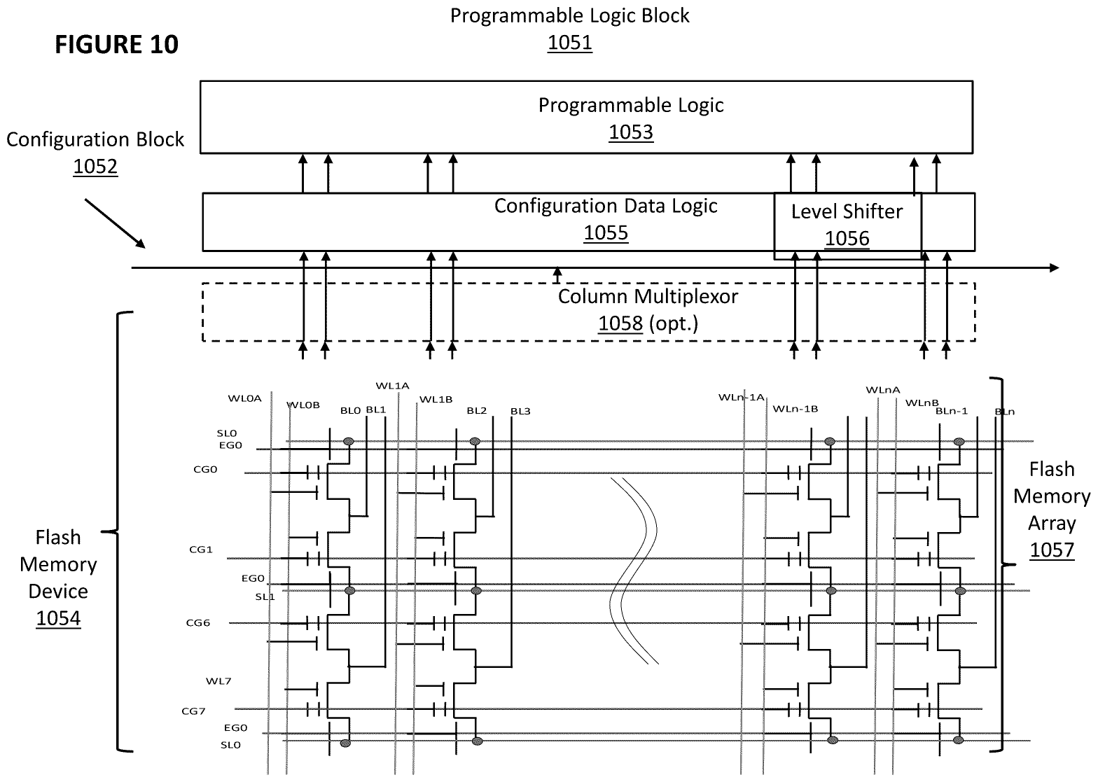

FIG. 10 depicts programmable logic block 1051, which is an example of programmable logic block 651 in FIG. 6B. Programmable logic block 1051 comprises configuration block 1052 and programmable logic 1053, which are examples of configuration block 652 and programmable logic 653 in FIG. 6B, respectively. Configuration block 1052 comprises flash memory device 1054 (which is an example of flash memory device 654 in FIG. 6B), which flash memory device 1054 comprises flash memory array 1057 and, optionally, column multiplexor 1058, and configuration data logic 1055 (which is an example of configuration data logic 655 in FIG. 6B).

Flash memory array 1057 comprises a plurality of flash memory cells arranged in rows and columns. Flash memory array 1057 further comprises word lines coupled to word line terminals of flash memory cells, control gate lines coupled to control gate terminals of flash memory cells, source lines coupled to source line terminals of flash memory cells, erase gate lines coupled to erase gate terminals of flash memory cells, and bit lines coupled to bit line terminals of flash memory cells. In this example, the control gate lines, source lines, and erase gate lines are horizontal (i.e., arranged in a first direction) and the word lines and bit lines are vertical (i.e., arranged in a second direction perpendicular to the first direction).

Column multiplexor 1058 is used during the programming operation of cells in flash memory array 1057 by providing a programming current, IPROG, to the cell being programmed. Column multiplexor 1058 also connects flash memory array 1057 to sense amplifiers for use during read or verify operations.

During a configuration operation of programmable logic 1053, read signals (such as bit line current or voltages corresponding to the bit line current) corresponding to the stored configuration data are obtained from flash memory array 1057. The read signals are provided to configuration data logic 1055 by column multiplexor 1058. Configuration data logic 1055 does one or more of enhancing the read signals such as by increasing or decreasing the voltage level of a ‘1’ bit and enhancing the signals by providing more functionalities for the outputs such as complementary signals or other functional logic signals and providing the enhanced configuration data to programmable logic 1053. In one example, configuration data logic 1055 comprises level shifter 1056, which receives voltages output from a sense amplifier (not shown), which had generated those voltages in response to read signals (such as bit line current) from flash memory array 1057.

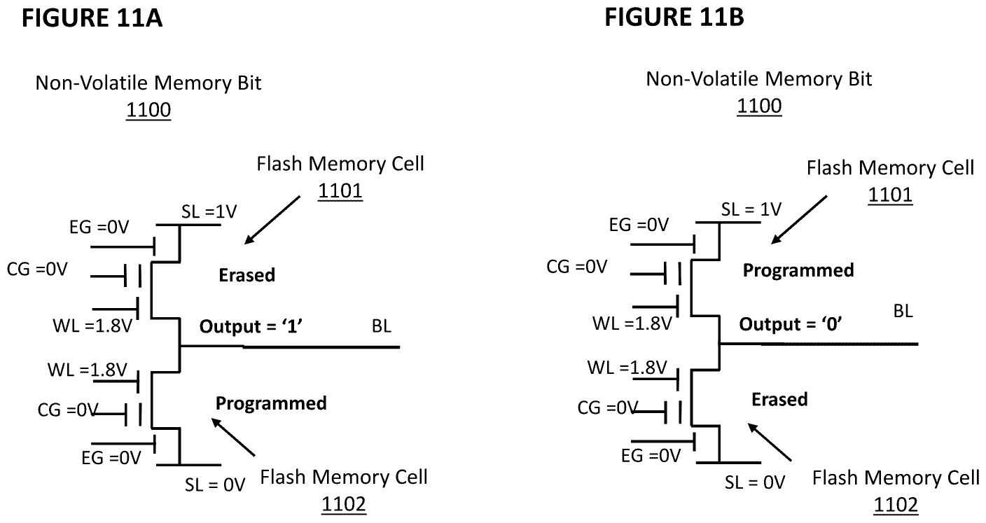

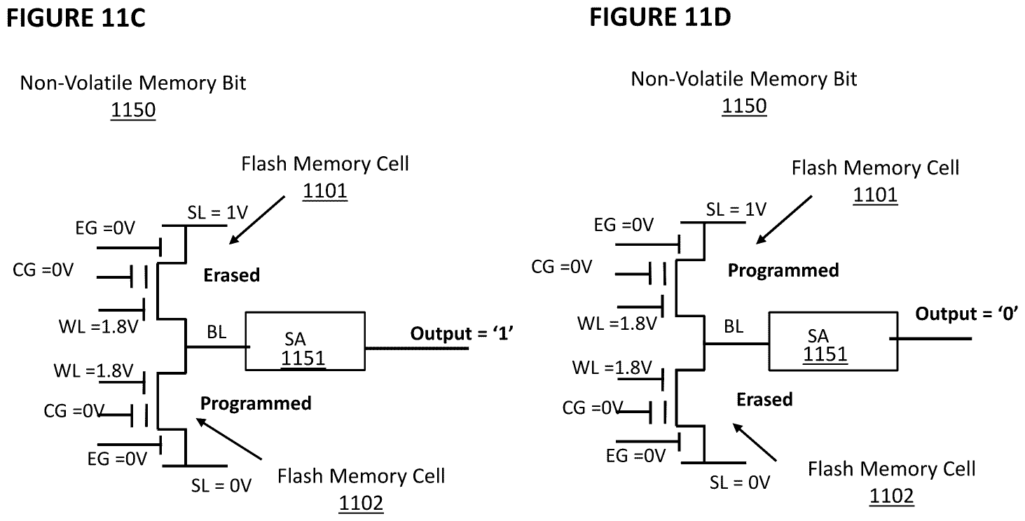

FIGS. 11A and 11B depict configurable non-volatile memory (NVM) bit 1100 in a configuration where adjacent flash memory cells (a pair of cells) that share a bit line are used to store a “1” or a “0.”. Flash memory cells 1101 (a first memory cell) and 1102 (a second memory cell) are adjacent cells in flash memory device 604, flash memory device 654, flash memory array 706, flash memory array 757, flash memory array 806, flash memory array 857, flash memory array 957, and flash memory array 1057 in FIGS. 6A, 6B, 7A, 7B, 8A, 8B, 9, and 10, respectively. Flash memory cell 1101 comprises a first erase gate (EG) terminal, a first source line (SL) terminal, a first control gate (CG) terminal, and a first word line (WL) terminal coupled to a first erase gate line, a first source line, a first control gate line, and a first word line, respectively. Flash memory cell 1102 comprises a second erase gate (EG) terminal, a second source line (SL) terminal, a second control gate (CG) terminal, and a second word line (WL) terminal coupled to a second erase gate line, a second source line, a second control gate line, and a second word line, respectively. Flash memory cells 1101 and 1102 each have a bit line terminal that connects to a shared bit line, at a shared drain terminal of flash memory cells 1101 and 1102.

In FIG. 11A, when flash memory cell 1101 is erased and flash memory cell 1102 is programmed, the output on the bit line during a read operation of both cells will be a “1.” due to the memory cell 1101 being in a full conducting state (high current state, erase state) and the memory cell 1102 is in a non-conducting state (no current state, programmed state). In FIG. 11B, when flash memory cell 1101 is programmed and flash memory cell 1102 is erased, the output on the bit line during a read operation of both cells will be a “0” due to the memory cell 1102 being in a full conducting state (high current state, erase state) and the memory cell 1101 is in a non-conducting state (no current state, programmed state). Because two memory cells (flash memory cells 1101 and 1102) are used to store a single bit of data and are continuously on, the storage is resilient against an error that can be injected due to an external force such as solar radiation. For instance, if the bit value stored in either flash memory cell 1101 or 1102 is changed due to an external event the output will still be valid due to the other flash memory cell, meaning that BL will still have a relatively high current to correctly output a “1” or will still have a relatively high current to correctly output a “0.”. And due to the always-on memory cells, the output state can recover from the transient effect.

FIGS. 11C and 11D depict configurable non-volatile memory (NVM) bit 1150 in a configuration where adjacent flash memory cells (a pair of cells) that share a bit line, coupled to a shared drain terminal, are used to store a “1” or a “0.” Non-volatile memory bit 1150 is similar to non-volatile memory bit 1100 in FIGS. 11A and 11B with the addition of sense amplifier 1151 to sense a signal on the shared bit line (BL) to generate digital output bits. Alternatively, the erased and programmed states of flash memory cells 1101 and 1102 can be interchanged, meaning that flash memory cell 1101 is programmed and flash memory cell 1102 is erased for output=1, and flash memory cell 1101 is erased and flash memory cell 1102 is programmed for output=0, with sense amplifier 1151 modified accordingly.

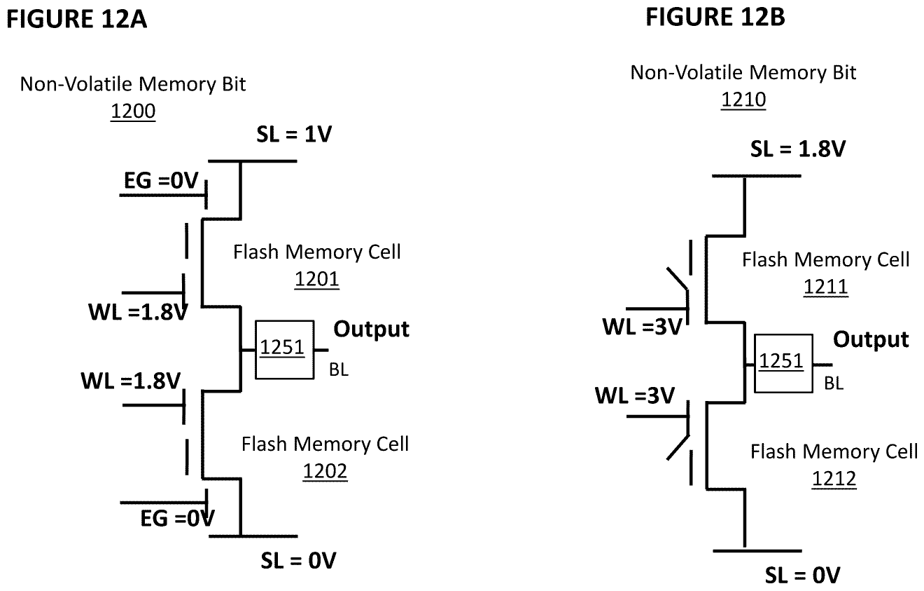

FIGS. 12A and 12B depict example non-volatile memory bits formed from adjacent flash memory cells that have different flash memory cell architectures.

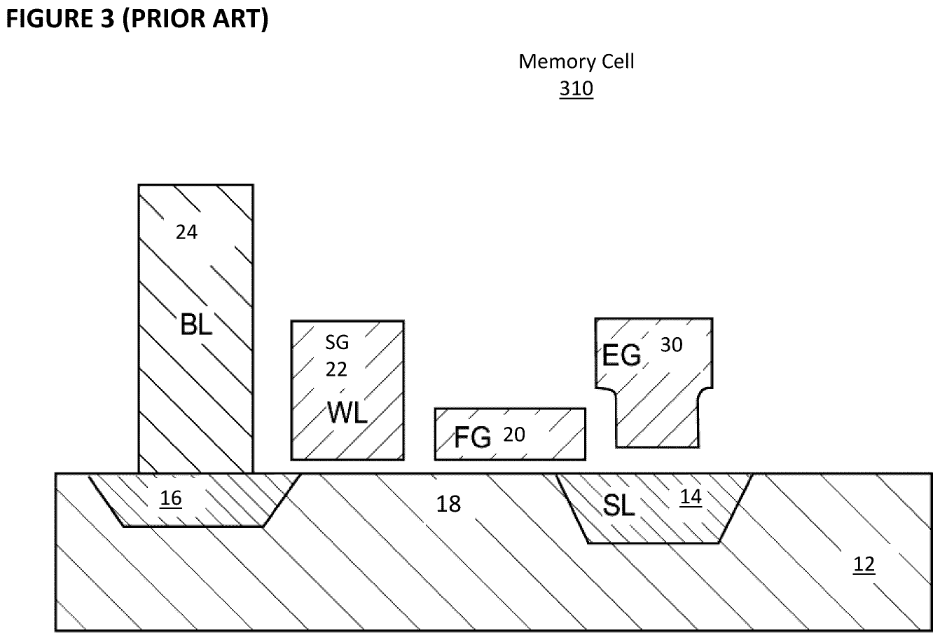

In FIG. 12A, non-volatile memory bit 1200 is formed from adjacent flash memory cells 1201 and 1202 that are of type flash memory cell 310 in FIG. 3. Sense amplifier 1251 is coupled to the shared bitline. Sense amplifier is used to convert the output signal from the bitline into a low impedance and possible shifted voltage level such as full power supply level.

In FIG. 12B, non-volatile memory bit 1210 is formed from adjacent flash memory cells 1211 and 1212 are of type flash memory cell 110 in FIG. 1. Due to the difference in operating voltages used with the two types of flash memory cells, an Output of “1” will be 1V in FIG. 12A but will be 1.8V in FIG. 12B.

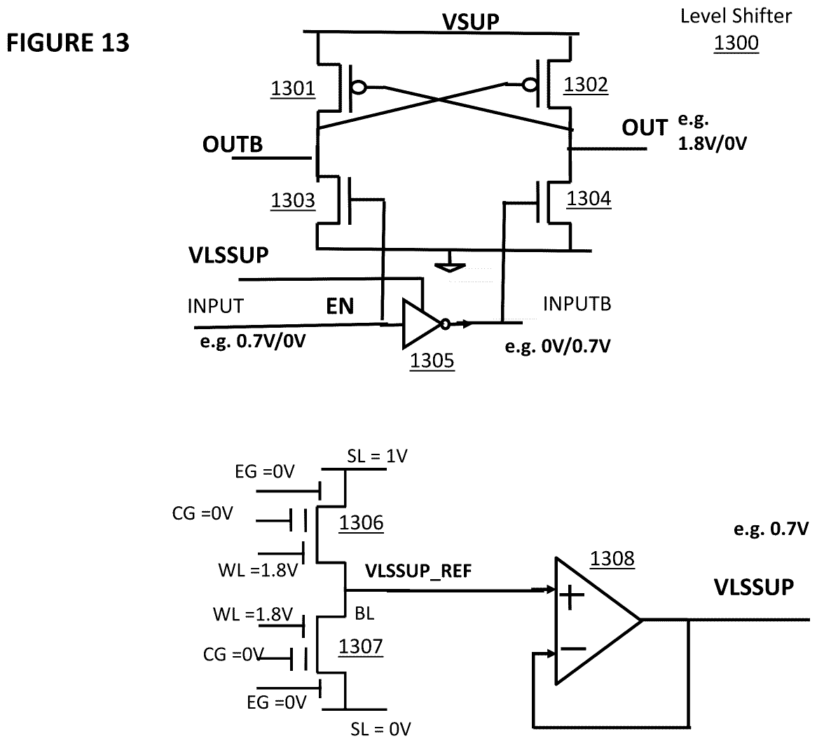

FIG. 13 depicts level shifter 1300, which can be used in any of level shifters 756, 856, 956, and 1056. Level shifter 1300 comprises cross-coupled PMOS transistors 1301 and 1302, NMOS transistors 1303 and 1304, and inverter 1305. Inverter 1305 receives the INPUT signal, which in this example can be 0V for a “0” or 0.7V for a “1”. Inverter 1305 inverts the INPUT and outputs the inverted value, INPUTB, as its output. Inverter 1305 receives VLSSUP as its supply voltage. An example level of VLSSUP is 0.7V.

The gate of NMOS transistor 1303 receives INPUT, and the gate of NMOS transistor receives INPUTB. When INPUT is high, INPUTB will be low, and NMOS transistor 1303 will be turned on and NMOS transistor 1304 will be turned off, such that OUTB is pulled to ground and is a “0”, which here is 0V. PMOS transistor 1302 receives OUTB at its gate and will be turned on, such that OUT will be pulled high to the value of VSUP, which here is 1.8V. PMOS transistor 1301 receives OUT at its gate and will be turned off.

When INPUT is low, INPUTB will be high, and NMOS transistor 1303 will be turned off and NMOS transistor 1304 will be turned on, such that OUT is pulled to ground and is a “0.” PMOS transistor 1301 receives OUT on its gate and will turned on, such that OUTB will be pulled high to the value of VSUP, which here is 1.8V. PMOS transistor 1302 receives OUTB on its gate and will be turned off. Thus, in this example, level shifter 1300 converts an input “0” of 0V to an output “0” of OV and an input “1” of 0.7V to an output “1” of 1.8V. Both complementary outputs OUT and OUTB are available for use by programmable logic, e.g. programmable logic 603, 703, 753, 803, 853, 953, or 1053.

The voltage VLSSUP is generated by the circuit comprising flash memory cell 1306, flash memory cell 1307, and operational amplifier 1308. Flash memory cell 1306 is erased and flash memory cell 1307 is programmed and as a result output a voltage VLSSUP_REF on their shared bitline. The non-inverting input of operational amplifier 1308 receives VLSSUP_REF, and the inverting input of operational amplifier 1308 is coupled to the output of operational amplifier 1308, which is VLSSUP, which is a buffered version of VLSSUP_REF. VLSSUP is the supply to input of the level shifter 1300 INPUT and INPUTB. This prevents leakage, such as leakage from inverter 1305 which might occur because the VGS of a PMOS transistor in inverter 1305 might not be zero (that is, the PMOS is not fully off during an off state; for example, the source of the PMOS might be 1V, typically Vdd core voltage, and its gate=<0.8V from INPUT, which is the signal from a flash memory array, not shown)). Optionally, outputs OUT and OUTB can themselves be used as a voltage source to another circuit.

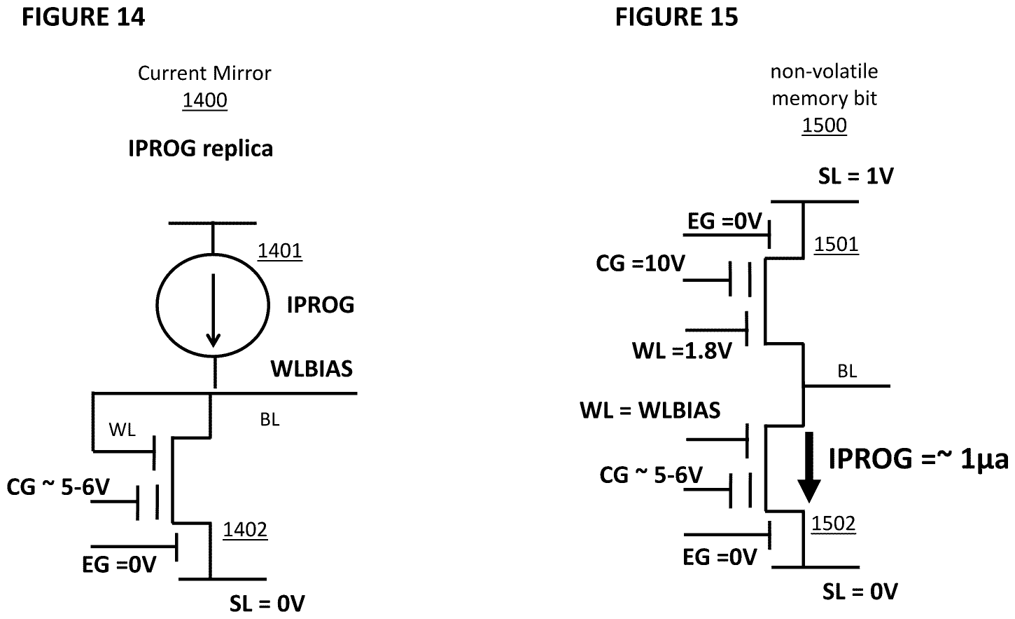

FIG. 14 depicts flash memory cell-based current mirror 1400, which comprises current source 1401 and a first memory cell, flash memory cell 1402, in a flash memory array. The word line (WL) terminal of flash memory cell 1402 is connected to the bit line terminal (BL), which bit line terminal (BL) is coupled to the output of current source 1401 so as to generate the desired voltage bias WLBIAS to control programming current, IPROG. This voltage bias can be applied to wordlines of a flash memory array for programming as shown in FIG. 15. In FIG. 15, non-volatile memory bit 1500 is formed from flash memory cells 1501 (a third memory cell) and 1502 (a second memory cell). In this example, the memory cell 1501 is to be programmed to store a value. The node generating WLBIAS in current mirror 1400 is provided to the word line terminal of the memory cell 1502 of the non-volatile memory bit 1500 to form a current mirror. The current IPROG will be drawn through flash memory cell 1502, as well as through flash memory cell 1501 as those cells are coupled together in series. The memory cell 1502 thus acts to provide programming current for the memory cell 1501 which is being programmed. Alternatively, the memory cell 1501 can acts as programming current for the memory cell 1502, in this case its wordline would be set to equal to the WLBIAS. Thus, flash memory cell 1402 in a flash memory array (such as in flash memory devices 604 and 654 in FIGS. 6A and 6B, respectively) itself is used to generate a programming current to program other cells (such as flash memory cell 1501) within the same flash memory array. This does not require the use of a column multiplexor during a programming operation as the programming current, IPROG, is generated by the flash memory array itself and does not need to be directed from an external programming source to the cell being programmed. The programmed cell (such as flash memory cell 1501) then can be used to provide a stored value to configure programmable logic such as programmable logic 603, 653, 703, 753, 803, 853, 953, and 1053.

As used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A system comprising:
a programmable logic block comprising programmable logic and a configuration block to store and provide configuration data to the programmable logic, the configuration block comprising a flash memory array to store the configuration data, and the flash memory array comprising an array of split-gate flash memory cells.

2. The system of claim 1, wherein the configuration block comprises configuration data logic to receive signals from the flash memory array based on the configuration data, modify the received signals into modified signals, and provide the modified signals to the programmable logic.

3. The system of claim 2, wherein the configuration data logic comprises a level shifter to generate modified signals with a different voltage level for a “1”.

4. The system of claim 1, wherein a respective bit of configuration data is stored in a plurality of adjacent memory cells in the flash memory array sharing a shared bit line.

5. The system of claim 4, wherein the plurality of adjacent memory cells comprises a first memory cell and a second memory cell and the bit of configuration data is a “1” when the first memory cell is erased and the second memory cell is programmed and the bit of configuration data is a “0” when the first memory cell is programmed and the second memory cell is erased.

6. The system of claim 1, wherein the configuration block comprises a column multiplexor.

7. The system of claim 1, where the flash memory array comprises source lines, control gate lines, word lines, and erase gate lines arranged in a first direction and bit lines arranged in a second direction perpendicular to the first direction.

8. The system of claim 1, where the flash memory array comprises source lines, control gate lines, word lines, erase gate lines, and bit lines arranged in a single direction.

9. The system of claim 1, where the flash memory array comprises source lines, word lines, and erase gate lines arranged in a first direction and control gate lines and bit lines arranged in a second direction perpendicular to the first direction.

10. The system of claim 1, where the flash memory array comprises source lines, control gate lines, and erase gate lines arranged in a first direction and word lines and bit lines arranged in a second direction perpendicular to the first direction.

11. The system of claim 1, comprising:
a second programmable logic block comprising second programmable logic and a second configuration block to store and provide second configuration data to the second programmable logic, the second configuration block comprising a second flash memory array to store the second configuration data.

12. The system of claim 1, wherein the split-gate flash memory cells are programmed using source side injection with hot electrons.

13. The system of claim 1, wherein the split-gate flash memory cells are programmed using a current source.

14. A method comprising:
forming a current mirror comprising a first memory cell in a flash memory array and a second memory cell in the flash memory array, a word line terminal of the first memory cell coupled to a word line terminal of the second memory cell, wherein the second memory cell draws a current; and
programming a value into a third memory cell using the drawn current, wherein a bit line terminal of the second memory cell is coupled to a bit line terminal of the third memory cell.

15. The method of claim 14, comprising:
configuring programmable logic using the value.

16. A system comprising:
a first memory cell coupled to a first erase gate line, a first control gate line, a first word line, a first source line, and a bit line; and
a second memory cell coupled to a second erase gate line, a second control gate line, a second word line, a second source line, and the bit line, wherein the second memory cell is adjacent to the first memory cell in an array of memory cells and the first memory cell and the second memory cell form a non-volatile memory bit;
wherein the non-volatile memory bit stores a “1” when the first memory cell is erased and the second memory cell is programmed and a “0” when the first memory cell is programmed and the second memory cell is erased.

17. The system of claim 16, comprising:
a level shifter that receives a “1” of a first voltage from the non-volatile memory bit and generates a “1” of a second voltage different than the first voltage.

18. The system of claim 17, wherein the second voltage is provided to a programmable logic to configure the programmable logic.

19. The system of claim 16, comprising:
a level shifter that receives a first voltage based on a value of the non-volatile memory bit and generates a second voltage, wherein the system uses the second voltage as a voltage source.

20. The system of claim 16, wherein the first memory cell is programmed and the second memory cell generates a current in response to the first memory cell.

21. The system of claim 20 comprising: a third memory cell that is programmed using the generated current.
